(19) United States
(12) Patent Application Publication
(10) Pub. No.: US 2020/0168248 A1
(43) Pub. Date: May 28, 2020

(54) READ-ONLY OPTICAL INFORMATION RECORDING MEDIUM AND SPUTTERING TARGET FOR FORMING REFLECTION FILM OF SAID OPTICAL INFORMATION RECORDING MEDIUM

(71) Applicant: Kabushiki Kaisha Kobe Seiko Sho (Kobe Steel, Ltd.), Kobe-shi, Hyogo (JP)

(72) Inventor: Yuki TAUCHI, Hyogo (JP)

(73) Assignee: Kabushiki Kaisha Kobe Seiko Sho (Kobe Steel, Ltd.), Kobe-shi, Hyogo (JP)

(21) Appl. No.: 16/611,409

(22) PCT Filed: Apr. 24, 2018
(86) PCT No.: PCT/JP2018/016680

§ 371 Date: Nov. 6, 2019

(30) Foreign Application Priority Data
May 11, 2017 (JP) 2017-094733

(51) Int. Cl. G11B 7/258; G11B 7/24062; C23C 14/34; G11B 7/24056; C23C 14/08; G11B 7/26

(52) U.S. Cl. CPC G11B 7/258; G11B 7/24062; C23C 14/3407; G11B 7/266; C23C 14/086; C23C 14/08; G11B 7/24056

(57) ABSTRACT

The present invention relates to a read-only optical information recording medium in which at least one reflection film and at least one light transmission layer are laid in order on a substrate and from which information is reproduced by blue laser. The reflection film includes a metal oxide containing Sn and Zn or a metal oxide containing In. The reflection film has a film thickness of 20 nm or more and 70 nm or less.

### TECHNICAL FIELD

The present invention relates to an optical information recording medium such as a read-only BD (Blu-ray Disc (registered trademark)) from which reproduction is performed using blue laser as well as to a sputtering target for formation of a reflection film of the optical information recording medium.

### BACKGROUND ART

Optical information recording media (optical discs) are generally classified into three types, that is, the read-only type, write-once type, and rewritable type, by the principle of recording and reproduction.

FIG. 1 schematically shows a typical structure of a read-only optical information recording medium (single-layer optical disc). As shown in FIG. 1, the read-only optical information recording medium 100 has a structure that a reflection film 20 having Ag, Al, Au, or the like as the main component and a light transmission layer 30 are laid in this order on a substrate 10 made of transparent plastic or the like.

The substrate 10 is, for example, a polycarbonate substrate of 1.1 mm in thickness and 12 cm in diameter and information is recorded on the substrate 10 in the form of a combination of projections and recesses called lands and pits (recorded data). The light transmission layer 30 is formed by, for example, applying and setting a light transmission resin. Reproduction of recorded data is performed by detecting phase differences or reflection differences of laser light irradiating the optical disc.

FIG. 1 shows the single layer optical disc in which a single-layer reflection film 20 and a single-layer light transmission layer 30 are formed on the substrate 10 in which information is recorded in the form of a combination of lands and pits. For example, as shown in FIG. 2, a double-layer optical disc having a first information recording surface 40 and a second information recording surface 50 is also used.

More specifically, the double-layer optical disc shown in FIG. 2 has a structure that a first reflection film 22, a first light transmission layer 32, a second reflection film 33, and a second light transmission layer 34 are laid in this order on a substrate 10 in which information is recorded in the form of a combination of projections and recesses, that is, lands and pits (recorded data). Information that is different from the information recorded in the substratet 10 is recorded in the first light transmission layer 32 in the form of a combination of lands and pits.

Au, Cu, Ag, and Al and alloys having these materials as a main component have been used commonly so far as the above-described reflection film(s) of optical discs.

Among those reflection films, reflection films having Au as the main component is superior in chemical stability (durability) and hence provides an advantage that the aging variations of the recording characteristics are small. However, they are very expensive and have a problem that they cannot exhibit sufficiently high reflectance for blue laser (wavelength: 405 nm) that is used for recording and reproduction of BDs, for example. Whereas reflection films having Cu as the main component are inexpensive, they are lowest in chemical stability among the conventional reflection film materials and are disadvantageous in that, like Au, they are low in the reflectance to blue laser. As such, reflection films having Cu as the main component are restricted in uses. In contrast, since reflection films having Ag as the main component exhibit sufficiently high reflectance in a wavelength range 400 to 800 nm of practical use and are high in chemical stability, at present, they are employed broadly in optical discs using blue laser.

On the other hand, whereas reflection films made of an Al-based alloy having Al as the main component are inexpensive and exhibit sufficiently high reflectance at the wavelength 405 nm, they are lower in durability than Ag-based and Au-based reflection films. Thus, to apply Al-based-alloy reflection films to DVD-ROMs (digital versatile disc read-only memories), attempts are being made to increase the durability by forming a sufficiently thick reflection film of about 40 nm.

However, where Al-based alloy reflection films having such a thickness are applied to BD-ROMs (Blu-ray disc read-only memories), HD DVD ROMs (high-definition digital versatile disc read-only memories), etc. that use blue laser, problems arise that a recorded signal (reproduction signal) is made low in accuracy (i.e., jitter is increased) and reproduction cannot be performed stably (reproduction stability is low).

On the other hand, in DVDs and BDs which have plural information recording layers, to record or reproduce a signal on or from the deep-side information recording layer as viewed from the laser light incidence side, it is necessary to use light that passes through the incidence-side layer as viewed from the laser light incidence side. However, where a thick Al-based alloy reflection film described above is used, the reflectance of the deep-side layer as viewed from the laser light incidence side is made small due to reflection and absorption in the incidence-side layer, resulting in a problem that sufficiently large S/N ratio (signal-to-noise ratio) cannot be obtained.

On the other hand, methods disclosed in Patent documents 1 to 4, for example, have been proposed to increase the reproduction stability or durability of an Al-based alloy reflection film.

Among these documents, Patent document 1 discloses an optical disc having an optical disc substrate that is formed with a pit row in which pits are arranged according to a recording signal, a reflection film that is deposited on the surface that is formed with the pits, and a light transmission layer that is formed on the reflection film. In this optical disc, in particular, when viewed from the side of the light transmission layer, the pit row includes minute pits that are 250 nm or less in length and width and the thickness of the Al, Ag, or Au reflection film is 20 nm or less.

In general, miniaturization of pits lowers the stability of signal reproduction. In Patent document 1, the jitter deterioration problem is solved by controlling the thickness of the reflection layer to 20 nm or less and the stability of signal reproduction is thereby increased. However, a problem remains that practically sufficient durability cannot be obtained if the thickness of the reflection film is decreased to 20 nm or less.

Patent document 2 discloses a technique for improving the jitter characteristic of a reproduction signal by controlling pits formed on a substrate surface and spaces between pits according to their relationships with a substrate length.

Patent document 3 discloses, in the Example section, an optical disc having an Al reflection layer (thickness: 100 nm) containing Ta at 4% as a reproduction-only optical disc that exhibits high durability even under conditions that temperature or humidity varies rapidly.

Patent document 4 discloses an Al-based alloy reflection film containing each of Cr, Fe, and Ti at 1 to 4%. This alloy composition makes it possible to provide a reflection film that is high in reflectance, has a smooth surface (Ra: about 5 to 10 nm), and low in the rate of growth of grains due to temperature variation and hence low in reflectance variation rate (high in durability).

### CITATION LIST

### Patent Literature

Patent document 1: WO 2000/65584

Patent document 2: JP-A-2006-66003

Patent document 3: JP-B-7-62919

Patent document 4: JP-A-2007-092153

### SUMMARY OF INVENTION

### Technical Problem

None of the methods disclosed in Patent documents 1 to 4 can attain both of high reproduction stability that is obtained by high reflectance and small jitter (fluctuation of a reproduction signal on the time axis is small) and sufficient durability even if they can attain one of them.

The present invention has been made in view of the above circumstances, and an object of the invention is therefore to provide a read-only optical information recording medium that has a reflection film and is suitably used as an optical disc using blue laser such as a BD-ROM or an HD DVD-ROM and that, in particular, is excellent in reproduction stability by virtue of high reflectance and small jitter and has high durability. Another object of the invention is to provide a sputtering target for formation of a reflection film of this optical information recording medium.

### Solution to Problem

The present inventors have studied diligently and completed the invention by finding out that a read-only optical information recording medium having a reflection film made of a particular metal oxide can solve the above problems.

That is, the invention relates to the following item [1]:

[1] A read-only optical information recording medium in which at least one reflection film and at least one light transmission layer are laid in order on a substrate and from which information is reproduced byblue laser,

wherein the reflection film comprises a metal oxide containing Sn and Zn or a metal oxide containing In and the reflection film has a film thickness of 20 nm or more and 70 nm or less.

A preferred embodiment of the invention relates to the following items [2] to [5]:

[2] The read-only optical information recording medium according to item [1], wherein the metal oxide containing Sn and Zn or the metal oxide containing In further contains at least one of W and Nb.

[3] The read-only optical information recording medium according to item [1] or [2], wherein the reflection film has a refractive index at a wavelength 405 nm of 1.9 or more and has an extinction coefficient at a wavelength 405 nm 0.1 or less.

[4] A sputtering target for formation of a reflection film of a read-only optical information recording medium that includes a structure that at least one reflection film and at least one light transmission layer are laid in order on a substrate and from which information is reproduced by blue laser,

the sputtering target comprising a metal oxide containing Sn and Zn or a metal oxide containing In.

[5] The sputtering target for formation of a reflection film of a read-only optical information recording medium according to item [4], the sputtering target further comprising at least one of W and Nb.

### Advantageous Effects of Invention

The invention can provide a read-only optical information recording medium that is excellent in reproduction stability by virtue of high reflectance and small jitter and has sufficient durability. The invention can also provide a sputtering target for formation of a reflection film of an optical information recording medium that exhibits the above performance.

### BRIEF DESCRIPTION OF DRAWINGS

FIG. 1 is a schematic sectional view of an essential part, in the circumferential direction, of a read-only optical information recording medium (single-layer optical disc).

FIG. 2 is a schematic sectional view of an essential part, in the circumferential direction, of another read-only optical information recording medium (double-layer optical disc).

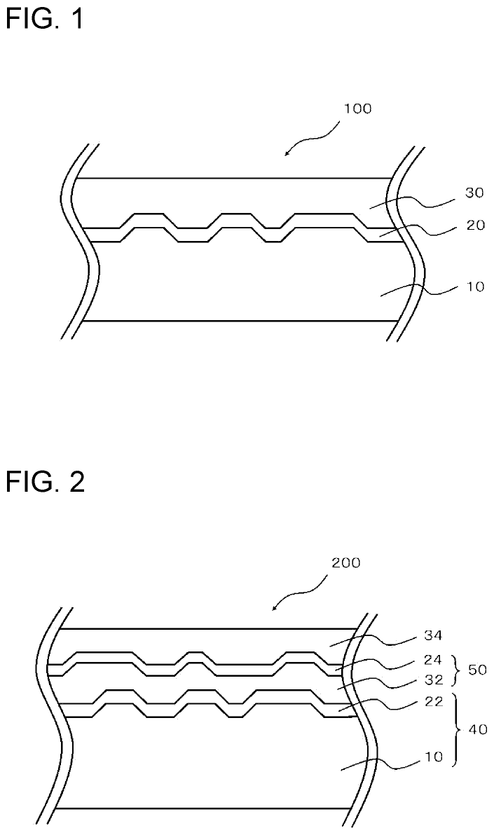

### DESCRIPTION OF EMBODIMENTS

The present inventors have studied diligently to provide a read-only optical information recording medium that is excellent in reproduction stability by virtue of high reflectance and small jitter and has high durability and, in particular, an optical information recording medium (optical disc) that can be used suitably as, for example, a BD-ROM and an HD DVD-ROM from which reproduction is performed using blue laser (in particular, a double-layer BD-ROM and HD DVD-ROM).

As a result, the inventors have found that excellent reproduction stability by virtue of high reflectance and small jitter and high durability are realized by applying a metal oxide containing Sn and Zn or a metal oxide containing In as a reflection film.

In this specification, the expression “excellent in reproduction stability” means that disc reflectance at an initial stage (before an accelerated environment test) is 5.0% or higher and an initial-stage jitter value is 8.5% or less, as described later in Examples. The term “high durability” means that a reduction of reflectance by an accelerated environment test in which a sample is held for 96 hours in an environment of temperature 80° C. and relative humidity about 85% (i.e., reflectance after the test minus reflectance before the test) is 10.0% or less (absolute value) and a jitter value after the accelerated environment test is 8.5% or less, as described later in Examples.

How the inventors have reached the invention is described below. To develop a new reflection film that uses a metal oxide and is excellent in reproduction stability and durability, the inventors studied, for each of various kinds of metal oxide materials, variations of optical characteristics and reproduction stability behavior caused by an accelerated environment test. More specifically, a single-layer BD-ROM disc was manufactured by light transmission forming each of various kinds of metal oxide thin-films at each of various film thicknesses by sputtering on a polycarbonate substrate that is formed with pits and lands, and then depositing a light transmission layer of an ultraviolet-curing resin. Then, it was subjected to measurement of a jitter value and durability. Results were as follows.

It was found that jitter value deterioration can be prevented while a high deposition rate is secured by using an oxide containing Sn (tin) and Zn (zinc) or an In (indium) oxide. It was also found that increase of the refractive index and further increase of reflectance can be attained by mixing W (tungsten) or Nb (niobium) into it.

It was found that, though the reflectance varies depending on the mixing ratio of the metal oxide, a reflection film can provide sufficient reflectance if its thickness is 20 nm or more. On the other hand, it was found that if the film thickness is more than 70 nm, the reflectance becomes too small and the reproduction stability lowers. When the crystallinity of each reflection film was checked, it was found that it had an amorphous structure and even after an accelerated environment test the amorphous structure was maintained with small variations in optical characteristics. The above-described experimental results show that the invention succeeded in determining a read-only optical information recording medium that is very excellent in reproduction stability and high in durability.

An embodiment of the invention is hereinafter described in a specific manner item by item. The invention is not restricted to the embodiment described below.

### Metal Oxide

A metal oxide that constitutes a reflection film used in the read-only optical information recording medium according to the invention is described below in detail.

The metal oxide according to the invention is a metal oxide containing Sn and Zn or a metal oxide containing In. When metal elements Sn and Zn are used, it is important to form a metal oxide using both of Sn and Zn. As described in Examples later, the advantages of the invention cannot be obtained by a metal oxide containing only one of Sn and Zn. On the other hand, where a metal element In is used, the advantages of the invention can be obtained by a metal oxide containing only In.

An Sn oxide, a Zn oxide, and an In oxide have a feature that the deposition rate of sputtering is high and exhibit a large refractive index. Using, as a material of a reflection film, a metal oxide containing both of Sn and Zn or a metal oxide containing only In makes it possible to decrease variations of optical characteristics caused by an accelerated environment test without lowering the refractive index.

This is considered because in the case of a metal oxide containing Sn and Zn, strain can be given to the structure of the reflection film due to a difference between the atomic radii of Sn and Zn, to cause it to make a transition to an amorphous structure. As a result, structure variation by an accelerated environment test can be suppressed. In the case of an In oxide, it is considered that structure variation caused by an accelerated environment test is small because of high structural stability of the In oxide containing only In.

On the other hand, in a metal oxide containing only Sn and a metal oxide containing only Zn, an accelerated environment test tends to cause crystallization. Thus, the above workings and advantages are not obtained.

As for a composition ratio of Sn, the composition ratio with respect to the total of all metal elements excluding O (oxygen) in a metal oxide (a metal element(s) other than Sn and Zn is also included if the metal oxide contains it) is preferably 95 atomic % or less, even preferably 90 atomic % or less. This is because the advantages of increased durability and reflectance can be obtained sufficiently when the composition ratio is within the above range. On the other hand, particularly from the viewpoint of securing necessary durability, the composition ratio of Sn is preferably 10 atomic % or more, even preferably 15 atomic % or more.

Likewise, as for a composition ratio of Zn, the composition ratio with respect to the total of all metal elements excluding O (oxygen) in a metal oxide is preferably 60 atomic % or less, even preferably 50 atomic % or less. This is because the advantage of increased durability can be obtained sufficiently when the composition ratio is within the above range. Likewise, from the viewpoint of increase of durability, the composition ratio of Zn is preferably 5 atomic % or more, even preferably 10 atomic % or more.

It is preferable that the metal oxide containing Sn and Zn or the metal oxide containing In according to the invention further contain at least one of W (tungsten) and Nb (niobium). Each of these elements makes it possible to secure an even larger refractive index when added to the metal oxide containing Sn and Zn or the metal oxide containing In. As a result, this makes it possible to realize higher reflectance in a reflection film of an optical information recording medium.

The reason why a large refractive index can be secured by adding the above metal element(s) is not clear. A possible explanation is that the metal oxide containing Sn and Zn or the metal oxide containing In maintains the amorphous structure without being affected by the bonding structure of the metal atom and oxygen in a tungsten compound or a niobium compound that exhibits a large refractive index in itself.

Where the metal oxide contains W, the composition ratio of W with respect to the total of all metal elements excluding O (oxygen) in the metal oxide is preferably 5 atomic % or more, even preferably 10 atomic % or more. This is because the advantage of increased reflectance is obtained when the composition ratio of W is within the above range. On the other hand, from the viewpoint of increase of durability, the composition ratio of W is preferably 80 atomic % or less, even preferably 70 atomic % or less.

Likewise, where the metal oxide contains Nb, the composition ratio of Nb with respect to the total of all metal elements excluding O (oxygen) in the metal oxide is preferably 3 atomic % or more, even preferably 5 atomic % or more. This is because the advantage of increased reflectance is obtained when the composition ratio of Nb is within the above range. On the other hand, from the viewpoint of the time taken by deposition (i.e., sputtering rate), the composition ratio of Nb is preferably 50 atomic % or less, even preferably 40 atomic % or less.

As described above, in the case where the metal oxide according to the invention is used as a reflection film, excellent reproduction stability obtained by high reflectance and small jitter and high durability can both be attained. Furthermore, the use of the metal oxide is advantageous in terms of manufacturing cost over conventional reflection films using Ag.

### Reflection Film

Next, the reflection film that is used in the read-only optical information recording medium according to the invention is described in detail.

As described above, the reflection film according to the embodiment includes a metal oxide containing Sn and Zn or a metal oxide containing In.

From the viewpoint of preventing the reflectance from being too small, the film thickness of the reflection film is required to be 20 nm or more, even preferably 30 nm or more. On the other hand, since the reflectance is decreased due to optical interference if the film thickness becomes too large, the film thickness of the reflection film is required to be 70 nm or less, even preferably 60 nm or less.

From the viewpoint of securing high reflectance, the refractive index at the wavelength 405 nm is preferably 1.9 or more, even preferably 2.0 or more. As for the extinction coefficient of the reflection film, if the extinction coefficient is too large which means that the light absorption rate is high, the transmittance becomes so small that the reflectance of a layer located on the deep side as viewed from the laser light incidence side becomes small. Thus, the extinction coefficient at the wavelength 405 nm is preferably 0.1 or less, even preferably 0.07 or less. Spectroscopic ellipsometry is employed as methods for measuring a refractive index and an extinction coefficient of a reflection film according to the invention.

### Other Part of Structure of Optical Information Recording Medium

The read-only optical information recording medium according to the invention is characterized in that the above-described metal oxide is used as a reflection film. There are no particular limitations on the structure and the type (the types of a light transmission layer, a substrate, etc.) of an optical disc to which the reflection film including this metal oxide is applied. They may be ordinary ones.

There are no particular limitations on the type of a substrate employed in the invention. Resins that are commonly used in optical disc substrates, such as a polycarbonate resin and an acrylic resin, can be employed. The use of a polycarbonate resin is preferable when a price, mechanical characteristics, etc. are taken into consideration.

It is preferable that the thickness of a substrate be approximately in a range of 0.4 to 1.2 mm. It is preferable that the depth of pits formed on a substrate be approximately in a range of 50 to 100 nm.

There are no particular limitations on the type of a light transmission layer; for example, an ultraviolet-curing resin, a polycarbonate resin, etc. can be used. It is preferable that the thickness of a light transmission layer be about 100 μm in the case of a single-layer optical disc. In the case of a double-layer optical disc, it is preferable that thicknesses of a first light transmission layer be about 25 μm and a second light transmission layer be about 75 μm.

The reflection film made of a metal oxide employed in the invention can be deposited by sputtering or evaporation, for example, and it is preferable to employ sputtering. This is because sputtering can provide optical characteristics and durability in a stable manner because the above-described metal elements and oxygen are dispersed uniformly and hence a uniform film can be obtained.

There are no particular limitations on the deposition conditions of the sputtering. For example, it is preferable to employ the following conditions:
Substrate temperature: room temperature to 50° C.
Ultimate pressure: 1×10⁻⁵ Torr or lower (1×10⁻³ Pa or lower)
Gas pressure during deposition: 0.1 to 1.0 Pa; Oxygen partial pressure: 1 to 50%
DC sputtering power density (DC sputtering power per unit area of target): 1.0 to 20 W/cm²

### Sputtering Target

It is preferable that the sputtering target for formation of a reflection film of a read-only optical information recording medium according to the invention be a metal oxide containing Sn and Zn or a metal oxide containing In. That is, it is preferable to use a metal oxide having basically the same composition as the reflection film according to the invention. Furthermore, as described above, it is preferable that the metal oxide containing Sn and Zn or the metal oxide containing In contain at least one of W and Nb. The use of the above sputtering target makes it possible to deposit a reflection film having a desired composition easily.

To perform sputtering stably using a DC power source, it is preferable that the volume resistivity of the sputtering target according to the invention be 1 Ω·cm or less.

Although the sputtering target can be manufactured by any of the melting and casting method, powder sintering method, spray forming method, etc., the use of the powder sintering method is preferable when productivity etc. are taken into consideration.

As for the deposition, it is possible to use a metal of Zn or Sn as a sputtering target by performing reactive sputtering in an oxygen atmosphere. However, the melting temperature of a metal of Zn or Sn is low, to avoid its melting during high power deposition, it is preferable to manufacture a sputtering target by the powder sintering method using an Sn oxide or a Zn oxide as a material. The material of each of W and Nb can be either a metal powder or a metal oxide powder.

### EXAMPLES

The invention is described below in more detail using Examples and Comparative Examples. However, the invention is not limited to Examples, and modifications are possible without departing from the spirit and scope of the invention and they are included in the technical scope of the invention.

### Examples 1

### Manufacture of Single-Layer BD-ROM

In Examples 1, various single-layer BD-ROMs (No. 1 to No. 13) shown in Table 1 were manufactured in the following manner.

First, a 1.1 mm-thick BD-ROM substrate was produced by injection-molding polycarbonate using an Ni stamper having lands and pits. Then reflection films having respective film thicknesses shown in Table 1 were formed on the thus-produced BD-ROM substrate by performing reactive sputtering in an oxygen atmosphere using metal oxide targets or metal targets having various compositions shown in Table 1 (each of the compositions of metal oxides of No. 2 to No. 13 shown in Table 1 indicates proportions of respective elements with respect to the total of all metal elements excluding O, respectively.

As for the sputtering conditions, the Ar gas flow rate was 20 sccm, the Ar gas pressure was 2 mTorr, the deposition power was DC 400 W, and the ultimate vacuum was 2.0×10⁻⁶ Ton. The thickness of a reflection film was controlled by varying the sputtering time.

Subsequently, a light transmission layer was formed by applying an ultraviolet-curing resin at a thickness 100 μm by spin coating and setting the resin by illuminating it with ultraviolet light. Single-layer BD-ROMs with a reflection film having each composition were manufactured in the above manner.

### Measurement of Jitter

Jitter was measured under the following conditions using ODU-1000 produced by Pulstec Industrial Co., Ltd. and the time interval analyzer TA820 produced by Tektoronix, Inc. In Examples, a sample whose initial jitter (before the accelerated environment test) was 8.5% or less was considered superior in reproduction stability and judged acceptable.
Reproduction laser power: 1 to 2 mW
Disc rotation speed: 4.98 m/s

### Measurement of Reflectance

Reflectance was measured by performing reproduction at reading power 0.35 mW using ODU-1000 of Pulstec Industrial Co., Ltd. and measuring a maximum level (reflection intensity (mV)) of a reflection signal using a digital oscilloscope (product name DL1640L) produced by Yokogawa Electric Corporation. This reflection intensity was converted into disc reflectance (a definition of the term “reflectance”). In Examples 1, samples whose initial disc reflectance (before an accelerated environment test) was 50% or more were judged acceptable.

### Evaluation of Durability

Part of the manufactured BD-ROMs were subjected to an accelerated environment test in which each sample was held for 96 hours in an air atmosphere of temperature 80° C. and relative humidity about 85%. In Examples, samples whose reduction of reflectance by the accelerated environment test (i.e., reflectance after the test minus reflectance before the test) was 10.0% or less (absolute value) and whose jitter value after the accelerated environment test was 8.5% or less were judged acceptable.

Results of the above measurements are shown in Table 1.

TABLE 1

| | | Reflection | | | After test | | |
|---|---|---|---|---|---|---|---|
| | | layer | Before test | | | Reflectance | |
| | Composition | Thickness | Jitter | Reflectance | Jitter | variation | |
| No. | (Atomic % ratio) | (nm) | (%) | (%) | (%) | (%) | Judgment |
| 1 | Pure Al | 40 | 25.0 | 80.0 | 10.0 | −12.0 | X |
| 2 | Sn oxide (Sn₁₀₀O) | 50 | 6.5 | 4.5 | 6.2 | −8.8 | X |
| 3 | Zn oxide (Zn₁₀₀O) | 50 | 7.2 | 7.0 | 7.0 | −17.5 | X |
| 4 | Sn₇₀Zn₃₀O | 50 | 6.7 | 5.1 | 6.2 | −3.8 | ◯ |
| 5 | Sn₅₀Zn₅₀O | 50 | 6.2 | 6.1 | 6.1 | −4.1 | ◯ |
| 6 | Sn₅₆Zn₂₄W₂₀O | 50 | 6.3 | 5.6 | 6.2 | −5.6 | ◯ |
| 7 | Sn₄₂Zn₁₈W₄₀O | 50 | 6.5 | 6.3 | 6.5 | −2.8 | ◯ |
| 8 | Sn₂₈Zn₁₂W₆₀O | 50 | 7.3 | 8.2 | 7.0 | −0.9 | ◯ |
| 9 | Sn₆₃Zn₂₇Nb₁₀O | 50 | 7.2 | 7.1 | 6.7 | −0.4 | ◯ |
| 10 | Sn₆₀Zn₂₆Nb₁₄O | 50 | 8.1 | 7.1 | 6.8 | −1.2 | ◯ |
| 11 | In oxide (In₁₀₀O) | 50 | 7.2 | 7.7 | 7.2 | 4.9 | ◯ |
| 12 | In₈₀W₂₀O | 50 | 7.7 | 8.4 | 7.4 | 1.9 | ◯ |
| 13 | In₈₀Nb₂₀O | 50 | 8.2 | 9.2 | 8.1 | −2.6 | ◯ |

The results shown in Table 1 are considered as follows. That is, in the reflection films that use the metal oxide(s) specified in the invention (No. 4 to No. 13 in Table 1), initial (before the accelerated environment test) reflectance values are large as 5.0 or more, and initial jitter values are small as 8.5% or less. Thus, it is read from the table that they are superior in reproduction stability. Furthermore, reflectance variations (i.e., reflectance reductions from the values before the accelerated environment test) are small as 10.0% or less (absolute values), and jitter values after the accelerated environment test are small as 8.5% or less. It is therefore read from the table that they are superior in durability. Based on the above results, No. 4 to No. 13 which are Examples of the invention are superior in both reproduction stability and durability and were judged to be “◯ (acceptable)” comprehensively.

In contrast, in the reflection films that do not use any metal oxide specified in the invention, such as a pure Al film, an Sn oxide, and an Zn oxide, high reflectance was not obtained or the durability was low, that is, the reflectance was decreased by the accelerated environment test or the jitter value after the accelerated environment test was large.

More specifically, in No. 1 in which the reflection film was a pure Al film, although the initial reflectance was very large, the reflectance was decreased much by the accelerated environment test. And the jitter was large both before and after the accelerated environment test.

In No. 2 in which the reflection film was a metal oxide containing only Sn, the initial reflectance was small. In No. 3 in which the reflection film was a metal oxide containing only Zn, the reflectance was decreased very much. Based on the above results, No. 1 to No. 3 which are Comparative Examples of the invention were poor in reproduction stability or durability and hence were judged to be “x (not acceptable)” comprehensively.

When comparison is made between No. 4 (Sn—Zn system) and No. 6 to No. 8 (Sn—Zn—W system) in which the composition ratio between Sn and Zn is the same, it is found that No. 6 to No. 8 in which W is added provide larger refractive indices and hence exhibit even larger reflectance values.

Likewise, when comparison is made between No. 4 (Sn—Zn system) and No. 9 and No. 10 (Sn—Zn—Nb system) in which the composition ratio between Sn and Zn is the same, it is found that No. 9 and No. 10 in which Nb is added provide larger refractive indices and hence exhibit even larger reflectance values.

Furthermore, when comparison is made between No. 11 (In system) and No. 12 (In—W system) and No. 13 (In—Nb system), it is found that No. 12 and No. 13 in which W or Nb is added provide larger refractive indices and hence exhibit even larger reflectance values. Based on these results, it is read from the table that the reflectance can be increased by adding W or Nb.

### Examples 2

To study the influence of the thickness of the reflection film made of the metal oxide specified in the invention, single-layer BD-ROMs was manufactured in the same manner as No. 4 (Sn₇₀Zn₃₀O) of Examples 1 except that the film thickness was varied as shown in Table 2.

Each single-layer BD-ROM thus manufactured was subjected to an initial jitter measurement and reflectance measurement (before the accelerated environment test) under the same conditions as in Examples 1. Samples whose initial jitter was 8.5% or less and initial disc reflectance was 5.0% or more were judged superior in reproduction stability and hence were judged to be “◯ (acceptable)” comprehensively. Samples that did not satisfy these requirements were judged to be “x (not acceptable)” comprehensively.

Results are shown in Table 2. In Table 2, jitter and reflectance measurement results of No. 14 and No. 18 are given a mark “-.” This means that jitter and reflectance could not be detected because of too small reflectance.

TABLE 2

| | Composition | Reflection layer | Before test | | |
|---|---|---|---|---|---|
| | (Atomic % | Thickness | Jitter | Reflectance | |
| No. | ratio) | (nm) | (%) | (%) | Judgment |
| 14 | Sn₇₀Zn₃₀O | 18 | — | — | X |
| 15 | | 30 | 2.5 | 6.2 | ◯ |
| 16 | | 50 | 6.7 | 5.1 | ◯ |
| 17 | | 70 | 3.3 | 7.5 | ◯ |
| 18 | | 90 | — | — | X |

In the results shown in Table 2, as described above, the reflection films made of metal oxide specified in the invention (No. 15 to No. 17 in Table 2) were 20 nm or more and 70 nm or less in film thickness and exhibited large initial reflectance values as 5.0 or more and small initial jitter values as 8.5% or less. It is thus read from the table that they are superior in reproduction stability.

Although Examples 2 employ Sn₇₀Zn₃₀O as a metal oxide specified by the invention, metal oxides specified by the invention other than Sn₇₀Zn₃₀O can be employed in a similar manner.

Although the invention has been described in detail by referring to the particular modes, it is apparent to those skilled in the art that various changes and modifications are possible without departing from the spirit and scope of the invention. The present application is based on Japanese Patent Application No. 2017-094733 filed on May 11, 2017, which is invoked in its entirety by reference.

### DESCRIPTION OF SYMBOLS

10: Substrate

20: Reflection film

22: First reflection film

24: Second reflection film

30: Light transmission layer

32: First light transmission layer

34: Second light transmission layer

40: First information recording surface

50: Second information recording surface

100: Read-only optical information recording medium (first optical disc)

200: Read-only optical information recording medium (second optical disc)

1. A read-only optical information recording medium from which information is reproduced by blue laser, comprising
at least one reflection film and at least one light transmission layer laid in order on a substrate,
wherein the reflection film comprises a metal oxide containing Sn and Zn or a metal oxide containing In and the reflection film has a film thickness of 20 nm or more and 70 nm or less.

2. The read-only optical information recording medium according to claim 1, wherein the metal oxide containing Sn and Zn or the metal oxide containing In further contains at least one of W and Nb.

3. The read-only optical information recording medium according to claim 1, wherein the reflection film has a refractive index at a wavelength 405 nm of 1.9 or more and has an extinction coefficient at a wavelength 405 nm of 0.1 or less.

4. A sputtering target for formation of a reflection film of a read-only optical information recording medium that includes a structure that at least one reflection film and at least one light transmission layer are laid in order on a substrate and from which information is reproduced by blue laser, the sputtering target comprising
a metal oxide containing Sn and Zn or a metal oxide containing In.

5. The sputtering target according to claim 4, further comprising
at least one of W and Nb.

6. The read-only optical information recording medium according to claim 2, wherein the reflection film has a refractive index at a wavelength 405 nm of 1.9 or more and has an extinction coefficient at a wavelength 405 nm of 0.1 or less.
